(19) United States
(12) Patent Application Publication
(10) Pub. No.: US 2005/0081909 A1
(43) Pub. Date: Apr. 21, 2005

(54) Concentrating solar roofing shingle

(76) Inventor: James B. Paull, Andover, MA (US)

Correspondence Address: Andover-IP-Law, Suite 300, 44 Park Street, Andover, MA, 01810, US

(21) Appl. No.: 10/968,293

(22) Filed: Oct. 19, 2004

Related U.S. Application Data
(60) Provisional application No. 60/512,641, filed on Oct. 20, 2003.

(51) Int. Cl. H01L 25/00

(52) U.S. Cl. 136/246

(57) ABSTRACT

This invention describes a non-imaging, non-tracking, integrally-formed solar radiation concentrator that passively concentrates both diffuse and direct solar radiation onto photovoltaic cells to produce electricity, incorporating its features into a shingle-like element useful as a roofing material and in other structural applications. The substantially transparent, solar concentrating elements of the invention may also incorporate a system to remove waste energy in the form of heat that is not utilized in the generation of electricity. The invention further provides a thermal energy recovery system including a forced convection air system for removing waste heat from the concentrating shingle assembly and using it, if desired, for building space heat or domestic water heating.

### BACKGROUND OF THE INVENTION

Solar energy concentrators are often used to increase the effectiveness of the collection of solar radiation and to lower the cost of energy absorbing materials. Tracking solar energy concentrators have reflectors that follow the path of the sun in one or two dimensions. While effective within operating limits, these known solar energy concentrators are designed to concentrate direct sunlight from the almost parallel rays of the sun, but typically they are not able to also take advantage of diffuse or scattered solar radiation. Moreover, the tracking mechanisms of these prior art devices can often be expensive and unreliable. In order to concentrate both direct and diffuse sunlight, several different types of non-tracking, non-imaging solar energy concentrators have been developed. Compound parabolic concentrators, such as those developed by Winston and others, use mirrors with multiple parabolic cross sections to direct sunlight onto absorbing targets. Similar reflector/concentrators take advantage of elliptical or hyperbolic curves to effect the concentration of sunlight. Another alternative approach uses a solid dielectric material in the compound parabolic shape that relies on the total internal reflection of light off of the edges of the material occurring at an angle less than the critical angle for the material and its surrounding medium.

Solar energy concentrators as described in the prior art are typically able to concentrate sunlight incident on the aperture of the concentrators in a ratio that is dependent on the angle of entering light reaching the absorbing target. This angle, known as the acceptance angle, determines the geometry of the concentrators and the ratio of concentration. For concentration in two dimensions, the ideal concentration C, which is the maximum theoretically obtainable for a given geometry, is given by the relationship C=1/sin α, where a is one half of the acceptance angle. For three-dimensional concentrators, an approximate ideal concentration ratio C can be calculated from the formula C=1/sin² α. For non-imaging concentrators using solid dielectric material, these theoretical limits are increased to n/sin α and n²/sin² α, respectively, where n is the refractive index of the dielectric material.

For these types of concentrators, all light within the acceptance angle will be reflected to reach the absorber. Conversely, light incident at the aperture of the concentrators outside the limits of the acceptance angle is reflected out of the concentrator and will not reach the absorbing target. This is only one of several problems with and limitations of the many prior art devices and systems for utilizing solar energy.

Thus, for example, U.S. Pat. No. 6,091,017, which patent is incorporated herein by reference, teaches a high efficiency, light weight solar concentrator array specially adapted for use with space vehicles. The solar concentrator panel of this patent is comprised of parallel rows of separate mirror assemblies mounted on a base plate having high thermal conductivity, with photovoltaic cells located along the base plate between the rows of mirror assemblies. Each concentrator array is made up of multiple separate mirror assemblies which need to be assembled with each other and with the photovoltaic cells before the array is operable to collect solar energy. This assembly is relatively large and would be relatively expensive to fabricate and assemble.

A shingle-like solar concentrator power module is shown in U.S. Patent Publication No. US 2003/0201007, which patent publication is also incorporated herein by reference. This patent publication teaches a solar power concentrating module comprising a planar base, an aligned array of linear photovoltaic cell circuits on the base, together with an array of linear Fresnel lenses or linear mirrors for directing focused solar radiation on the photovoltaic cell circuits. The separate Fresnel lenses or linear mirrors are assembled with each other and with the photovoltaic cell circuits, and the entire device can then be encapsulated by lamination for weather protection. Although this process results in a relatively thin, shingle-like product, this fabrication involves multiple component parts and assembly steps and, as a result, is relatively costly.

Still another example of a photovoltaic panel is taught by U.S. Pat. No. 6,440,769, which patent is also incorporated herein by reference. This patent teaches a fabrication method that includes the sequential steps of shaping a thin film into a plurality of parabolic shaped concentrators, forming an aperture in the bottom of each of the parabolic shaped concentrators, coating the concentrators with a reflective material, encapsulating the concentrators with a transparent insulating layer, depositing a photovoltaic cell on the bottom of the parabolic shaped concentrators, and depositing an anti-reflection coating on the top of the parabolic shaped concentrators. Although this invention is touted as being a low cost fabrication process for making a photovoltaic device, the multiple component parts, which need to be assembled in proper alignment/orientation, and the multiple fabrication process steps would make the resulting products relatively high in cost.

Another type of solar cell assembly is described in U.S. Pat. No. 6,008,449, which patent is also incorporated herein by reference. This assembly comprises a specially designed reflective member having first and second opposite surfaces, one being transparent to allow incident radiation to pass into the reflective member, while the second surface has a plurality of reflective portions positioned to receive the radiation and to reflect and focus it toward the first surface. Because the radiation strikes the first surface at an angle that is greater than a critical angle of the first surface, it is reflected and focused back toward the second surface. This assembly also includes a solar cell positioned close to the reflective member to receive focused radiation and to generate electric current from that radiation.

U.S. Pat. No. 5,167,724, which patent is also incorporated herein by reference, describes yet another, somewhat earlier design for a planar photovoltaic solar concentrator module. This design involves positioning a solar cell having electrical terminals in the hollow interior of an electrically insulating housing. The front wall of the housing comprises a lens that operates to direct solar radiation incident on the lens into the interior of the housing. A refractive optical element in contact with the solar cell and facing the lens receives the solar radiation that passes into the interior of the housing by the lens and directs it to the solar cell. Here again, the solar radiation collection device is comprised of multiple component parts which must be properly assembled and oriented, as well as being connected to electrical circuitry.

Another type of solar collection system for utilizing solar energy is described in U.S. Pat. No. 6,700,054, which patent is also incorporated herein by reference. This design is specifically intended to better harness diffuse light and to achieve concentration of incident solar energy without requiring accurate solar tracking or high precision reflectors by utilizing a specially designed tapering reflective element in accordance with Snell's law.

A concentrating coverglass design for use with photovoltaic cells is described in U.S. Pat. Nos. 5,959,787 and 6,091,020, which patents are incorporated herein by reference. Somewhat older designs for concentrating solar radiation collectors are taught in U.S. Pat. Nos. 4,143,234; 4,166,917; 4,003,638; 4,440,153 and 4,002,299, which patents are also incorporated herein by reference.

There are several practical limits to the usefulness of compound parabolic concentrators and similar solar energy devices as described above. First, the degree of concentration that is attainable given a reasonable range of acceptance angles is limited. Second, the compound parabolic concentrator geometry is such that the height of the concentrating structure is typically several times that of the concentrator aperture, resulting in a structure which is relatively large, ungainly and expensive. Third, to be practical non-imaging concentrators must incorporate features to allow excess heat to be removed from an absorber, such as a photovoltaic cell, and to provide protection from the environment, such as rain and wind. In addition, as discussed above, prior art solar energy devices are typically comprised of multiple component parts which must be meticulously assembled in the proper orientation, tend to be somewhat fragile, are generally expensive to fabricate and assemble, and are not readily adaptable to mass construction applications that do not require specially skilled installers.

These and other limitations of and problems with prior art systems for concentrating sunlight are overcome in whole or in part by the concentrating roofing shingles of the present invention.

### OBJECTS OF THE INVENTION

Accordingly, it is a general object of the present invention to provide a sturdy, durable, relatively inexpensive, non-imaging, non-tracking, integrally-formed solar concentrator designed as a shingle or comparable planar element that can be easily installed and used in a side-by-side or overlapping array as a roofing material, or in skylight, facade or other building material applications, or in a stand-alone arrangement to collect solar radiation while also protecting the solar collector system from weather.

A further object of this invention is to fabricate and use a concentrating shingle or comparable building/roofing element to direct sunlight, both diffuse and direct, over a wide range of incident altitude and azimuth angles to an absorbing target such as a photovoltaic cell.

It is yet a further object of the invention to provide an effective means of manufacturing the concentrating shingle described herein.

It is yet a further object of the invention to incorporate means of creating pleasing visual effects using the optical properties of the concentrating shingle.

It is yet a further object of the present invention to incorporate an integrally-formed light concentrating structure within a concentrating shingle or comparable roofing or building/construction element such that the concentrating structure is itself an integral part of the weather-protecting shingle.

It is yet a further object of this invention to provide a system or design to remove heat from the primary absorbing target, such as a photovoltaic cell, to prevent overheating of the target and also optionally to use such excess heat, if desired, for building or water heating.

These and other objects, benefits and advantages of the apparatus and methods of this invention will be better understood from the following description, which is intended to be read in conjunction with the several drawings.

### SUMMARY OF THE INVENTION

The essence of the present invention is to incorporate non-tracking, non-imaging, integrally-formed solar concentrating elements into a substantially sunlight-transparent shingle material or comparable roofing/building element made for example of a material such as plastic or glass. A concentrating solar structure in accordance with this invention comprises a two-layer structure consisting of an upper substantially planar portion (the light-receiving portion) which serves as a protective glazing and supporting structure for the integrally-formed solar radiation concentrating elements formed in the lower substantially planar portion (the light-concentrating portion). These two portions of the solar concentrating structure of this invention can be separately fabricated and later adhered along the upper surface of the light-concentrating portion. Alternatively, after formation the light-concentrating portion of the structure can be glazed or coated along the upper surface to provide the protective light-receiving portion of the structure. In a preferred embodiment of the invention, however, the two layers of the solar concentrating structure are integrally formed as a unitary structure including integrally-formed light concentrating elements in the light-concentrating layer of the device. As used herein, the term “integrally-formed light concentrating element” means that a light-concentrating geometry (as described hereinafter), or a plurality of such light-concentrating geometries, is permanently formed in or created as an integral part of a single, discreet physical structure in a material that lends itself to the formation of internal light-concentrating geometries.

At the bottom or base of the integrally-formed light concentrating elements incorporated into the shingle are photovoltaic cells used to absorb the concentrated solar radiation and convert it to electricity. Electric circuitry connected to the photovoltaic cells collects the electricity produced for immediate use or for delivery to an electricity storage system (e.g., a capacitor, a battery, or other such storage means). In one embodiment of this invention, finned heat sinks are attached to the bottom of the photovoltaic cells to dissipate excess heat that otherwise might be detrimental to the performance or physical life of the structure. The solar concentrating shingles or elements of this invention can be specially designed or adapted, for example in ways discussed hereinafter, to serve as a roofing material. The solar concentrating elements of this invention can also be adapted for alternative uses such as for windows, walls, and other structural components.

The preferred integrally-formed light concentrating elements to be formed into the shingle structure of this invention are of a geometry known in the art as a focusing or concentrating geometry, such as a compound parabolic concentrator. A compound parabolic concentrator is a reflecting structure of such geometry such that light incident on the aperture of the structure within a certain range of angles, known as the acceptance angle, will be directed to an absorbing target. As is also known in the art, this reflection can also be accomplished by using a solid dielectric material whereby light is reflected internally within the dielectric as long as the angle of incidence of light with respect to the angle of the walls of the dielectric is less than the critical angle for total internal reflection for the material. It has been found in accordance with this invention that such light-concentrating geometries can be integrally formed into the interiors of certain dielectric materials such as acrylic, other plastics and glass either manually using suitable tools or more preferably, using such conventional manufacturing techniques such as injection molding or extrusion. In general, a fabrication process using injection molding is most preferred.

The critical angle for total internal reflection imposes a limit on the acceptance angle and on the degree of concentration of a non-imaging concentrator element. For example, a dielectric with a refractive index of 1.5 would typically have a maximum acceptance half angle of 31 degrees; i.e., light at any higher angle of incidence would not be reflected internally within the concentrating element. Such limitation can be overcome, at least in part, by applying reflective surfaces to the outside of the concentrating elements. At the same time it should be understood that, even within a theoretically calculated range, some portion of the accepted light may exceed the critical angle for the material(s) being used and therefore may not reach the target. The compound parabolic concentrator structure is used here as an example; but, it will be understood that other non-imaging reflective geometry, such as hyperbolic reflectors and elliptical reflectors, as also known in the art, can be utilized in such applications as well.

A principal advantage of the present invention compared with prior art approaches is that the present invention permits a substantial reduction in the amount of relatively expensive photovoltaic material which is needed. Practical concentration ratios with the present invention can range from about 3:1 to about 8:1, depending on acceptance angles and the choice of two or three-dimensional concentration, as discussed further below.

A concentrating shingle designed for two-dimensional concentration in accordance with this invention will have multiple concentrating element profiles integrally formed in its lower planar portion. These profiles or geometries, resembling ridges or channels, will each have a lateral axis running the width of the concentrating shingle, normally aligned in an east-west direction when installed. If the profiles are designed to reach the limit for total internal reflection for a dielectric having a refraction index of about 1.5, the concentrating elements will be able to concentrate both diffuse and direct sunlight incident on them over an incidence angle of approximately 62 degrees in the plane of the shape of the concentrating element. If the axis of the profiles is aligned east to west, such 62 degree incidence angle corresponds to the acceptance angle of the altitude of the sun or other incident radiation. Radiation over the azimuth angles incident on the plane of the concentrating shingles would thus be reflected onto the absorbing surface as long as the width of the structure is wide enough to avoid losses at the edges.

The upper planar portion of a substantially light-transparent shingle in accordance with this invention serves as a supporting structure for the solar concentrating elements integrally formed in its lower planar portion. Incident sunlight striking the upper surface of such dielectric material will be refracted to a steeper angle because of the higher refractive index of the dielectric. Light will then enter the concentrating element profile in the lower part of the shingle and will be internally reflected so long as the angle of incidence of light with respect to the sides of the profile is less than the critical angle of the material.

In a preferred embodiment of the invention, a portion of the concentrating shingle along at least one edge (typically what will be the lower edge upon installation) is formed without the lower concentrating profiles. This allows for a flat piece of transparent material to overlap the shingle below it, providing the weather resistance afforded by conventional shingle roofing. Such overlap also protects an opening in the lower shingle to allow for fasteners to attach the shingle to a roof or other supporting structure. It is also possible to practice this invention without the overlapping lip portions on the shingles. For example, adjacent shingles could be joined either in the factory or in the field by heat fusion, solvent welding or other techniques commonly known in plastic or glass fabrication to ensure a weather-tight construction along the width of a shingle assembly, such as a roof. In such an alternative embodiment of this invention, all edges of the shingle element could be joined together using the techniques described above.

In another preferred embodiment of the invention photovoltaic material, for example formed as a ribbon structure, is attached to the bottom of the concentrating elements to receive the concentrated sunlight. In some embodiments, the underside of the photovoltaic material may also comprise a heat sink, which may have fins to help dissipate excess heat to the air space below.

The materials comprising thin film photovoltaics are typically deposited on a supporting substrate such as glass or stainless steel film. Recently, work in the field has led to efforts by some photovoltaic manufacturers to deposit photovoltaic materials on plastic as a substrate. In another embodiment of the present invention based on these emerging technical developments, it is envisioned that the photovoltaic material would be deposited directly on the plastic or glass at the location of the absorbing target of the concentrating lenses. Such deposition might be accomplished by manufacturing procedures known in the art, such as roll transfer or sputtering. Thus, a manufacturing process in accordance with the present invention could be simplified, and the number of steps would be reduced, by eliminating the need to separately adhere photovoltaic strips to the bottoms of the concentrating lenses.

A concentrating shingle for three-dimensional concentration in accordance with this invention is of similar construction to a two-dimensional concentrator, as described above, with the difference that instead of a two-dimensional profile extending along an axis, the integrally-formed concentrating profiles are in two planes, thereby forming integral concentrating cone geometries at the bottom planar portions of the shingles instead of forming ridges or channels as discussed for the two-dimensional embodiment. The profiles of these concentrating cones can vary in mutually perpendicular planes to accommodate different acceptance angles and degrees of concentration corresponding to desired ranges of azimuth and altitude angles of incident sunlight to be accepted by the concentrator. As in the two-dimensional concentrator design, reflective surfaces can be applied to the outsides of the cones to overcome the limitations on total internal reflection as discussed above. Instead of a ribbon shape, for this application the photovoltaic material at the bottom of the concentrating elements would preferably be of approximately round or oval shape.

Standoff legs or other types of spacers, which may be fastened to the bottom of the concentrating shingles of this invention, can be used both to attach the shingles to the supporting structure or the roof below it and to provide for an intermediate air space to be used for natural or forced convection of air to remove excess heat generated by the photovoltaic cell. Alternatively, shingles can be supported by other means, such as from their edges.

In a typical installation, solar concentrating shingles according to this invention will be installed at a non-zero angle relative to the horizontal, as is common in solar installations. Openings at the bottom of a shingle will allow cooling air to be introduced to the air space below the concentrating shingles. This air can either come from the outside or from a building, and it can be drawn through the space by natural convection or by forced convection using for example a fan or other air circulation device. Hot air removing excess heat from the shingles can either be vented at the top of the shingle assembly or be introduced into a building to provide building heat or to heat water by using a heat exchanger, or for other useful thermal applications.

Another aspect of this invention relates to a novel manufacturing technique using a novel magnetic jig to prepare solar concentrating shingles in accordance with this invention. Important to this invention is an effective means of manufacture. In one embodiment, narrow ribbons of thin-film photovoltaic material are adhered to each of the concentrating lenses. In practical applications these ribbons will be quite narrow, typically on the order of 1 to 3 mm, and as they do not necessarily stay flat and straight due to their being a film, some practical means is needed to handle the narrow ribbons in order to accurately align them to the bottoms of the concentrating lenses for adhesion.

At least one type of thin film photovoltaic has been found to exhibit the quality of being attracted by a magnetic field: namely, copper indium di-selenide (CIS). This serendipitous quality is utilized in the present invention in a manufacturing procedure to align and position a multitude of narrow photovoltaic strips so that they can be readily adhered to the concentrating lenses.

The procedure uses a jig formed in the approximate negative mold shape corresponding to the profile of the lenses of the underside of the concentrating shingle. The jig is constructed from a suitable non-ferrous solid material, such as plastic or ceramic. In one embodiment of the invention, an electromagnet (or multiple electromagnets) is built into the material of the jig below and in proximity to the channels in the jig. In another embodiment of the invention, a magnet or magnets (electromagnet or permanent magnet), separate from the jig, is brought into proximity to the jig as necessary to affect the magnetic attraction of the thin film photovoltaic.

In the manufacturing process, a plurality of narrow photovoltaic strips is deposited over the jig with their longitudinal axes approximating that of the channels in the jig. This can be done by hand, by using a grate with longitudinal slits approximating the opening and spacing of the jig below it, or other automated means that will distribute the photovoltaic ribbons into the top of the channels of the magnetic jig. Alternatively, the photovoltaic ribbons could be introduced into the top of the channels one-by-one, such as from a moving dispenser.

A magnetic field is applied to the area of the bottom of the jig, either through the permanent or electromagnet mentioned above. The magnetic field pulls and aligns the photovoltaic ribbons to the bottom of the channels. This can be done with one common magnetic field, however in the preferred embodiment electromagnetic coils are built into the jib below the bottom of each channel. The magnetic field from the electromagnetic coils is shielded from the adjoining channels by materials known in the art so that the effect of a particular electromagnetic coil is substantially limited to its respective channel. In this way, the magnetic attraction in each channel can be controlled independently.

The photovoltaic strips that are aligned and held at the bottom of the channels may be in one of two orientations: either the active photovoltaic surface or the metallic film surface may face upwards. The desired (active) orientation is to have the photovoltaic surface face upwards. In order to ensure the correct orientation, optical sensors are used to determine the side of the photovoltaic ribbon facing upwards at the bottom of the channels. As the photovoltaic surface will be dark and the metallic surface will be shiny, the intensity of light reflected back from the photovoltaic ribbon will indicate which side is facing upwards. Channels with the film in the proper orientation will have their respective magnetic fields remain on; magnetic fields in the other channels will be turned off. Then all un-magnetized channels will then be cleared of photovoltaic ribbons by air jets or other suitable means.

The above process is repeated until the optical sensors indicate that all channels are filled with photovoltaic ribbons in the proper orientation. When this occurs, a concentrating shingle with adhesive applied to the bottom of the concentrating lenses will be positioned into the magnetic jig so that the adhesive surface makes contact with the photovoltaic ribbons. The magnetic fields holding the ribbons to the bottom of the channel are then switched off, and the concentrating shingle is removed from the jig with the photovoltaic ribbons attached.

The logic of the optical sensors and the switching of the electromagnets may be controlled by a programmable logic controller (PLC), as is known in the art.

Still another aspect of this invention relates to the use of reverse optics to create visual effects with the solar concentrating shingles of this invention.

The light impinging on a concentrating shingle of this invention that is within the range of the designed acceptance angle will necessarily be directed to the absorbing photovoltaic target. For an observer looking at the shingle at an angle that is within the range of the acceptance angles, the reverse effect is also true, i.e. the observer will only see light reflected from the absorbing target. For most photovoltaic materials this will a black or dark gray color.

However, an observer viewing the shingle from outside the acceptance angle will not see the color of the photovoltaic target, but will rather see light that emanates from other than the target and either passes through, is reflected or is refracted by the clear concentrating shingle. This would be the case, for example, if a roof was at a 45-degree pitch, the acceptance half-angle was at 31 degrees, and the observer was at street level. The observer would be within a 14 degree angular range where the observer would not see the color of the photovoltaic target.

This affords the opportunity to create a desirable visual effect for an observer viewing the shingle from outside the acceptance angle. These effects include creating perceptions of texture and/or color. In the present invention, the effects are created by inserting background sheets of material or other objects that give the illusion of color or texture. This effect can greatly enhance the appearance of a roof formed of the solar concentrating shingles of this invention and thereby help to overcome objections on aesthetic grounds that some people have with solar installations.

As the background sheets do not touch the surface of the concentrating lenses, they do not interfere with the optics of internal reflection. The non-imaging optics does not lend itself to projecting coherent detail, but it can be used to project color or shades of color, colored bars and shade variations on the surface of the background material can be used to create the appearance of texture. Depending on the visual effects desired, the background sheets could be flat or shaped to optimize the projected optics, such as formed in wedge shapes to fit in the spaces between the concentrating lenses. Alternatively, the heat dissipating fins themselves can be colored to create the desired visual effects, as much of the light not striking the absorbing target takes a path such that it strikes the area occupied by the heat fins either directly under the concentrating lens or under an adjoining concentrating lens. The sheets can be constructed of any suitable material such as a metallic foil that could be shaped as necessary and withstand environmental conditions such as extremes in temperature. The background sheets can be supported independently or can be supported off part of the concentrating shingle itself, such as the heat dissipating fins attached to the photovoltaic target.

### BRIEF DESCRIPTION OF THE DRAWINGS

FIG. 1 is a schematic sectional view through a solar concentrating element in accordance with this invention showing the limits of acceptance angles for total internal reflection.

FIG. 2 is a schematic orthogonal view of a two-dimensional solar concentrating element in accordance with this invention with a photovoltaic cell and heat sink attached.

FIG. 3 is a schematic orthogonal view of a three-dimensional solar concentrating element in accordance with this invention with a photovoltaic cell and heat sink attached.

FIG. 4 is a schematic sectional view through an individual solar concentrating shingle in accordance with this invention.

FIG. 5 is a schematic sectional view through an assembly of solar concentrating shingles in accordance with this invention installed as roofing material.

FIG. 6 is a schematic sectional view of a solar concentrating shingle assembly in accordance with this invention in conjunction with a thermal dispersal system for removing and/or utilizing waste heat.

FIG. 7 is a schematic sectional view through an individual solar concentrating shingle incorporating intermediate light targets.

FIG. 8 is a schematic orthogonal view of elements of equipment used for manufacture of a solar concentrating shingle.

### DESCRIPTION OF PREFERRED EMBODIMENTS OF THE INVENTION

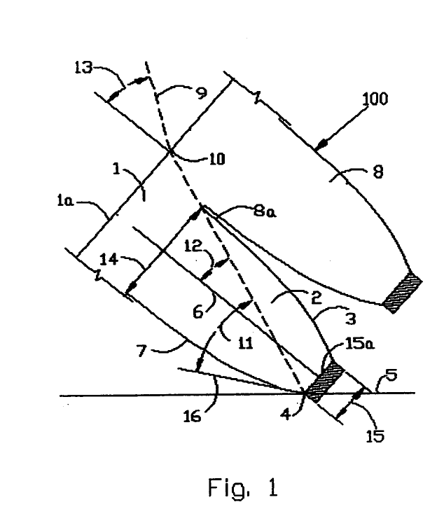

Referring to the drawings, FIG. 1 shows a section through a portion of a solar concentrating roofing shingle 100 in accordance with one embodiment of the present invention. For illustration, FIG. 1 shows two integrally-formed parabolic concentrating structures side-by-side. For purposes of example, the shingle 100 of FIG. 1 may be constructed of transparent acrylic material, although it could also be constructed of other plastic materials or glass. The embodiment of FIG. 1 is for two-dimensional concentration of light onto a photovoltaic absorber. A three-dimensional solar concentrating shingle in accordance with another embodiment of the present invention will be described in connection with subsequent drawings.

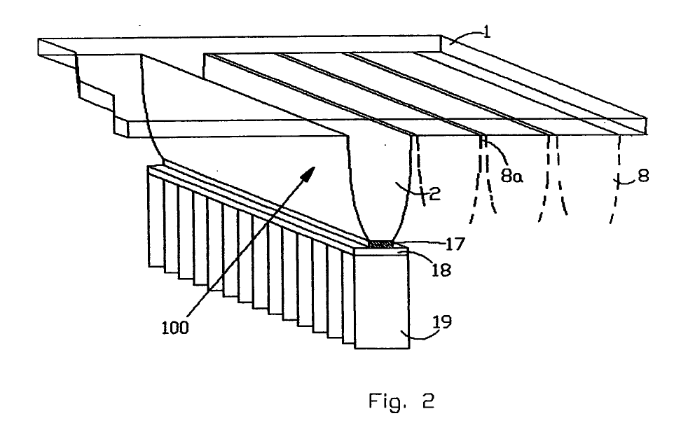

The upper glazing 1 of the concentrating shingle 100 is a continuous sheet of a substantially sunlight-transparent material that serves to protect the lower component of the shingle from the weather and to serve as a supporting structure for an integrally-formed concentrating element 2, a plurality of such elements being integrally-formed in the shingle's lower surface. Adjacent concentrating elements 8 are preferably positioned as closely together as manufacturing tolerances allow to minimize optical losses from the regions 8a between the integrally-formed concentrating elements (as shown in FIG. 2, the widths of the regions 8a along upper glazing 1 have been exaggerated for illustration).

In this invention embodiment, the integrally-formed concentrating element structure is formed in the shape of a compound parabolic concentrator. This type of solar energy concentrator, as known in the art, is based on two distinct parabolic reflectors directing light incident on the aperture of the concentrator over a defined angular range, known as the acceptance angle, onto a smaller absorbing target at the base of the parabolic reflectors. In this embodiment of the invention, reflection of light within the concentrator is accomplished by total internal reflection of light impinging on the edges of the structure at an angle of incidence less than the critical angle for total internal reflection, which is determined at least in part by the material and its surrounding medium (in this case, air).

The parabolic shape of an edge 3 of concentrating structure 2 can be determined according to the focus of the associated parabola at a point 4 that is coincident with the intersection of edge 3 with the opposite-facing parabolic edge 7 of the concentrator with the outside edge of the upper surface 15a of the target or absorber 15, in this case a photovoltaic cell. The axis of the parabola that is defined in part by edge 3 is represented by line 5. The optimum parabolic shape of an opposite-facing edge 7 of the structure may be determined in a similar fashion, and preferably so as to be symmetrical around the axis 6 of the concentrating element, which axis 6 is itself normal to a plane defined by the upper side or surface 1a of the glazing 1 of the shingle 100.

The angular limit of the concentrating structure 2 to direct incident light to the absorber is represented in FIG. 1 by an edge ray trace, such as by the light ray 9, incident on the upper surface 1a of the shingle 100 at the point 10 at an angle of incidence 13 from a normal relative to the plane of the upper surface of the shingle. Upon entering the glazing, which has a higher refractive index, the light ray 9 is refracted to an angle 12 from the normal relative to the surface plane (which angle 12 is less than angle 13). Light ray 9 then passes through the outside edge of the concentrator aperture 14 and strikes one edge of the target/absorber at the point 4, which is the intersection of the upper surface 15a of the absorber 15 with the parabolic edge 7.

This ray trace represents the limit of the concentrating structure to direct light to the absorber 15 for an angle of incidence 13. All light at an angle of incidence greater than 13 will not reach the target; conversely all light at an angle of incidence less than 13 will reach the target. The angle 12 is known as the acceptance half-angle. Such acceptance half-angle is a function of the width of the concentrating structure aperture 14 relative to the width of the absorbing face or surface 15a of absorber 15. The acceptance half-angle determines the maximum degree of concentration according to a mathematical formula. For a two-dimensional concentrating structure, the maximum theoretical concentration C is given by the formula C=1/sin α, where a is the acceptance half-angle 12.

There is a further inherent limitation in using total internal reflection in a dielectric material as the means of concentrating light on an absorber. Over the range of acceptance angles 12, in order for a ray of light to reach the absorber, the angle of incidence of the ray with the edge of the concentrating structure must be less than the critical angle of the dielectric material for total internal reflection. The extreme case of this condition is also represented by ray 9 in FIG. 1 in that after being refracted to half-angle 12, ray 9 impinges on the opposite-facing parabolic edge 7 of the structure at the intersection of edge 7 with the absorbing surface of absorber 15. Over a range of acceptance angles, this is where the angle of incidence 11 will be highest, such angle of incidence being defined by the angle 11 between the tangent 16 to the parabolic edge 7 at its junction with the absorbing surface and the refracted light ray 9. The angle 11 must be less than the critical angle Ac, which is given by the formula Ac=arc sin (1/n), where n=the refractive index of the dielectric material.

FIG. 2 is a schematic view of a portion of a two-dimensional concentrating shingle assembly 100 in accordance with one embodiment of this invention showing a different perspective of the upper protective and supporting glazing surface 1 in relation to the lower integrally-formed concentrating structure 2 as shown in FIG. 1. FIG. 2 also shows how a plurality of additional integrally-formed parabolic concentrating structures 8 adjacent to and in axial alignment with the axis of structure 2 might be incorporated into the shingle 100.

Adhered to or embedded into and along the bottom of each integrally-formed concentrating structure at its absorbing base is a photovoltaic material 17 (corresponding to target 15 in FIG. 1), for example ribbon crystalline silicon, selected or adapted for the generation of electricity from absorbed sunlight or other suitable light energy source. Multiple photovoltaic cells in the shingle assembly are preferably connected by appropriate electrical connections (not shown) in order to provide a collective power output to a building or another electrical distribution network. As shown in FIG. 2, in another preferred embodiment of the invention, a heat sink is attached to the bottom of the photovoltaic strip 17 to dissipate excess heat from energy incident on the absorber but not converted to electricity. In the embodiment illustrated in FIG. 2, the heat sink comprises a metal plate 18 to absorb heat from the photovoltaic strip 17 and to transfer such thermal energy to heat transfer fins 19 projecting from plate 18. The metal plate 18 also serves as a support for the projecting fins 19. Air passing over the fins based either on natural or forced convection carries excess heat away from the shingle assembly. It is within the scope of this invention, however, to use the shingle assembly of this invention in combination with alternative heat sink/thermal energy dissipation devices including systems for recovering and using such excess thermal energy.

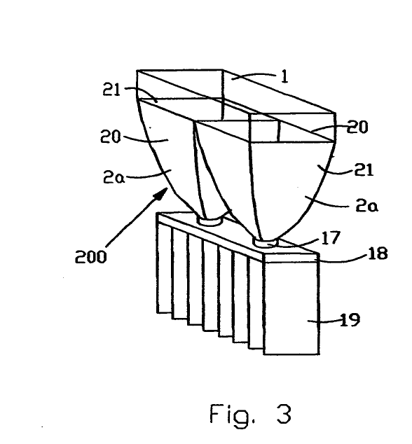

The integrally-formed concentrating structures as shown in FIGS. 1 and 2 can alternatively be configured to concentrate radiation in three dimensions instead of two. Referring to FIG. 3, the integrally-formed concentrating structures can each be designed in two mutually perpendicular planes in order to concentrate sunlight incident in directions corresponding to the variation in both the sun's altitude and azimuth. FIG. 3 shows two adjacent concentrating elements 2a comprising the lower portion of the protective and supportive glazing surface 1 of a shingle assembly 200 in accordance with this alternative embodiment of the invention. The concentrating elements 2a are configured in two planes with edge geometry in their respective planes substantially comprising compound parabolic concentrator curves similar to the parabolic geometry of the structures 2 and 8 in FIG. 1. Parabolic curves 20 are designed to concentrate light incident in a first plane, while parabolic curves 21 are designed to concentrate light in a second plane substantially normal to the first plane. While these curves 20 and 21 may be of substantially the same parabolic (or other curved) shape, they may also be of different geometry to allow for differences in concentration ratios and acceptance angles and to adjust to the solid angle of incident radiation that it is desired to capture. As described above in connection with the two-dimensional concentrator, light is reflected internally by the dielectric material to reach the absorbing photovoltaic target 17. The absorbing target 17 in FIG. 3 (as well as in the embodiments of FIGS. 1 and 2) may be square, oval, round, or any other suitable shape depending on the desired geometry of the concentrating element above it. Slight accommodations in the parabolic curves to accommodate the transition in shape of the aperture opening to the shape of the target/absorber can usually be made without substantially affecting the optical performance of the concentrating shingle. Thus, for example, if in a particular plane a higher range of acceptance angles is desired that would otherwise cause the critical angle for internal reflection to be exceeded, a reflective surface can be applied to one or more outside surfaces of the concentrating elements to accommodate this design.

As described above in connection with the two-dimensional solar energy concentrator designs, a photovoltaic cell assembly operating in conjunction with the three-dimensional concentrating structures is in thermal communication with a heat sink, which, as shown in FIG. 3, may comprise a metal substrate 18 and a plurality of metal heat transfer fins 19 to dissipate excess heat.

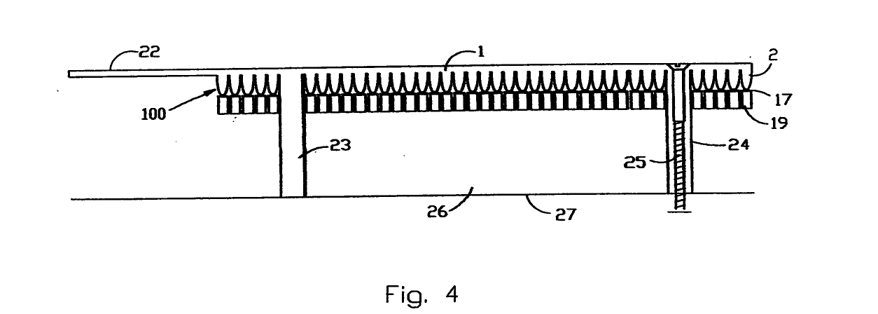

FIG. 4 is a schematic sectional view through a concentrating shingle 100 comparable to that of FIGS. 1 and 2, comprising upper transparent glazing layer 1, a plurality of adjacent lower concentrating elements 2, a set of electrically connected photovoltaic absorbing strips 17, a heat sink base 18 (not seen in FIG. 4) and sets of heat sink fins 19. The upper transparent glazing 1 as shown in FIG. 4 is extended to form a protruding lip 22 designed to overlap an adjacent concentrating or other shingle and to protect the assembly from the weather. A first set of supporting legs 23 are attached to the lower side of shingle 100 at intervals to provide support for the shingle and to act as spacers to create an air plenum 26, providing a space for air to carry away excess heat. In a preferred embodiment of the invention, a second set of supporting legs 24 is provided. In addition to also providing the functions mentioned above for legs 23, legs 24 preferably have a hollow center aligned with an aperture in the upper glazing 1 to receive a fastener 25, such as a screw fastener, to secure the shingle to roofing material or other backing structure 27. The hollow support and fastener hole is preferably positioned proximate to an edge of shingle 100 such that it will lie under the overlapping lip section 22 of an adjacent shingle. This hole may be further protected from the weather by use of a gasket seal (not shown) below the fastener head.

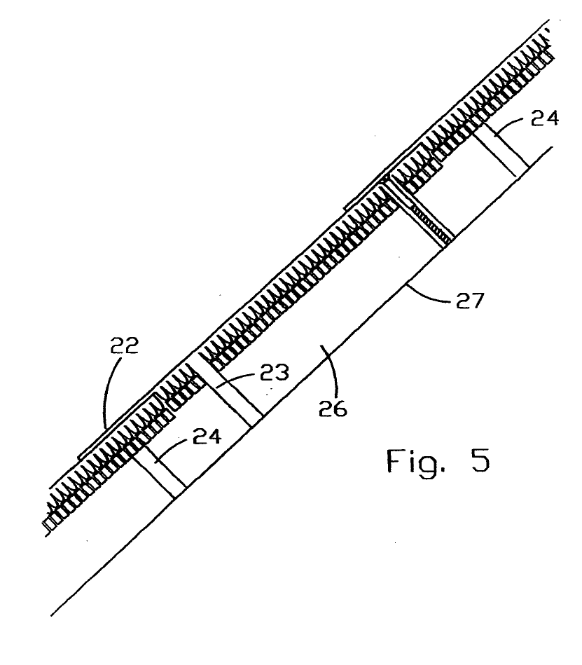

FIG. 5 is a schematic sectional view of an assembly of concentrating shingles in accordance with this invention as they might appear attached to a roof or other suitable supporting structure. The overlapping lip section 22 of one shingle provides weather resistance from rain and ice, and it also serves to protect the openings for fasteners in the shingle immediately below it as described above in connection with FIG. 4. A notch (not shown) or a clip in a shingle into which an edge of an adjacent shingle would fit could be used in other embodiments of this invention to provide additional security from wind forces acting on the assembly. The backing or roof structure 27 may be solid roofing material; or, if it is a stand-alone structure, it may have openings (not shown) to allow additional air to flow through the air plenum 26 to assist in removing excess heat. The shingle assembly is designed to either be mounted at the angle of the roof, as shown in FIG. 5, or on a separate supporting structure that is installed at an angle calculated to optimize the radiation incident on the concentrating shingle assembly. Normally with a two-dimensional concentrator as illustrated in FIGS. 1 and 2, the shingles will be installed on the roof or other structure such that the axes of the respective concentrator profiles are oriented in a generally east-west orientation such that the shingles will concentrate radiation in a dimension consistent with the variation in altitude of the sun.

As previously described, in an alternative embodiment of this invention, instead of using overlapping lip portions, concentrating shingles installed side by side in accordance with this invention may also be joined together by joining their edges together by heat fusion, solvent welding, adhesive or other means commonly known in the art or trade.

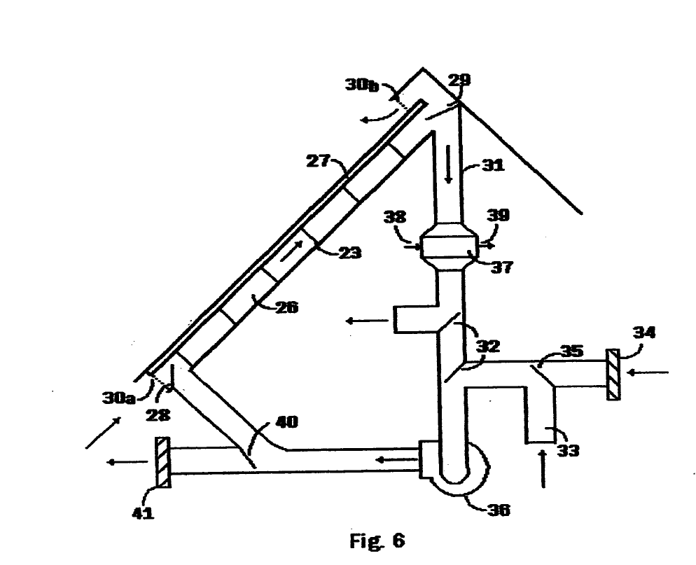

FIG. 6 is a schematic side view of a thermal energy recovery system designed to remove and utilize waste heat generated by a concentrating solar shingle assembly in accordance with this invention. The system is shown as it might be installed on an angled roof of a building, with the shingle-covered roofing assembly 27 shown with stand-off/supporting legs 23 creating a convective air plenum 26 underlying roofing assembly 27.

The system as shown in FIG. 6 is able to operate in various modes depending on the extent of the cooling required to maintain a desired temperature for the concentrating shingle assembly and also on the demand by the building for such waste heat.

In a first mode designed to cool the shingle assembly by natural convection only, air enters the plenum 26 at a lower screened opening or inlet 30a. Air heated by waste heat from the shingle assembly rises by natural convection, passes through plenum 26 and discharges at a peak roof vent at the upper screened opening or outlet 30b. Lower and upper dampers, which may be operated by damper actuators, can be used to close off this natural convection circuit from the ducts in the other parts of the system.

In a second mode of operation, if the waste heat load is high enough as to require a supplemental removal mechanism, for example by forced convection, a fan 36 or similar air circulation device may be used to draw outside air for cooling into plenum region 26 of the shingle assembly at lower opening 30a. Damper element 29 can be used to direct the heated air through return duct 31 into the circulating fan 36. Such recirculated air entering the fan 36 can first be passed through an air-to-water heat exchanger 37, where, if desired or needed, the hot air can be used to heat domestic hot water. (The inlet and outlet for the water to and from the heat exchanger 37 are indicated respectively at 38 and 39.) Damper element 40 can then direct the waste hot air from circulating unit 36 through discharge louver 41 instead of to inlet 30a.

In a third mode of operation, when building heat is needed, damper elements 28 and 40 can be closed to the outside such that air to the plenum region 26 is supplied solely from the circulating fan 36. Air leaving the plenum region is again directed to return duct 31. Damper elements 32 can be positioned so that heated air is directed to the building interior for space heating and so that the inlet to the fan 36 is isolated from the return duct 31. In this mode of operation, air is brought into the fan 36 via outside air louver 34 and building space duct 33. The relative amounts of air brought to fan 36 are modulated by damper 35 to maintain a balance between fresh outside air volume and mixed return/outside air temperature. All three modes of operation as described above may be controlled by a building automation system (not shown).

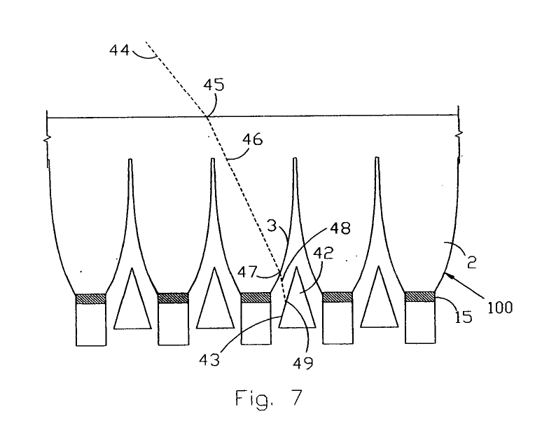

FIG. 7 shows another sectional view through a portion of a solar concentrating roofing shingle 100. Included in this embodiment are intermediate light targets 42 positioned between the lenses of the concentrating lens structure 2. The purpose of the targets 42 is to offer surfaces that reflect color to an observer situated outside the range of optical acceptance angles that otherwise would cause the observer to see the color of the photovoltaic target. The axis of the targets 42 in the longitudinal plane normal to the section is preferably substantially the same as the longitudinal axis of the concentrating lenses.

The intermediate light targets 42 can be solid or hollow and may be made from almost any solid material. The shape of the light targets in the plane of the sectional view can be a polygon or can be a sheet oriented vertically, horizontally or and angle in between. As an example of a preferred embodiment, the light targets 42 as shown in FIG. 7 are triangular and made from heavy metallic foil, such as aluminum. The triangular shape provides structural integrity to the target so that it can be independently supported at the respective ends or edges of the concentrating shingle.

The surfaces 43 on the light targets 42 are colored as necessary to achieve the desired visual effect to an observer. Typically these surfaces will be dark gray or black over the entire surface to match the appearance of the photovoltaic material, but in other embodiments the surface may be partially colored or have strips or other irregular colorings in order to give the roofing shingle the appearance of texture, which may be a desirable visual effect.

In another variation of this embodiment, the size of the light targets 42 can be varied to let more or less light pass by the concentrating shingle 100 in order to provide varying degrees of daylighting on the interior side of the shingle.

A secondary benefit of using the light targets 42 is that they can absorb solar radiation that is not directed to the photovoltaic target 15. This will help capture additional thermal energy for use, if desired, in space or water heating.

Again referring to FIG. 7, the drawing schematically shows an example of a light ray outside of the acceptance angle for the concentrating optics that would be directed to the light target 42 rather than the photovoltaic 15. Such a light ray 44 incident on the upper surface of the concentrating shingle 100 is refracted to a steeper angle at the interface 45 and follows path 46 through the concentrating element. As the light ray 47 intersects the edge 3 of the concentrating element, the angle of the ray with respect to the angle of the edge is greater than the critical angle for total internal reflection, so the light ray exits the concentrating element and is refracted to the ray path 48. The ray then strikes the surface 43 of the light target 42 at point 49. Light reflected back to an observer viewing from light ray path 44 from point 49 on the light target surface 43 will follow exactly the same path in reverse; hence the observer will see the color of the light target 42 at point 49.

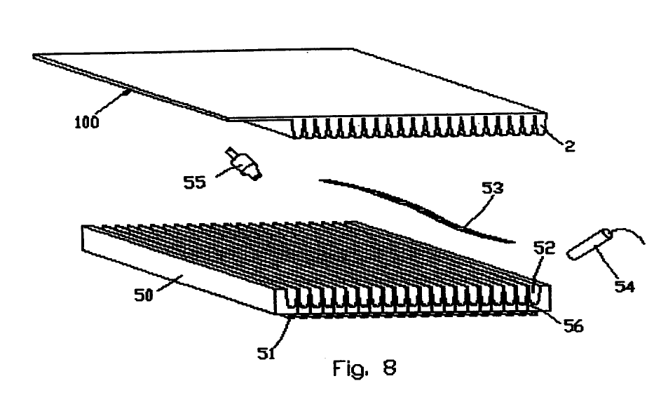

FIG. 8 shows a schematic orthogonal view of equipment that can be used in a manufacturing procedure that utilizes a magnetic jig for preparing one type of solar concentrating shingle in accordance with this invention. The procedure illustrated in FIG. 8 uses a jig 50 formed in the approximate negative mold shape corresponding to the desired profile of the concentrating lens elements 2 of the underside of the concentrating shingle 100. The jig is constructed from a suitable non-ferrous solid material, such as plastic or ceramic. In this embodiment of the invention, electromagnet elements 51 are attached to the jig below and in proximity to the multiple channels 52 along one surface (e.g., the upper surface) of the jig.

In the manufacturing process in accordance with this embodiment, a plurality of narrow photovoltaic strips 53 is deposited over the jig 50 with their longitudinal axes approximating that of the multiple channels 52 in the jig. This can be done by hand, by using a grate (not shown) with longitudinal slits approximating the opening and spacing of the jig below it, or using other automated means that will appropriately distribute the photovoltaic ribbons into the tops of the channels of the magnetic jig 50. Next, using appropriate electrical circuits, magnetic fields are applied to the area of the bottom or lower surface of the jig by means of the electromagnets 51. The magnetic field pulls and aligns the photovoltaic ribbons 53 to the bottoms of the channels 52. The magnetic field from the electromagnetic coils 51 is shielded from the adjoining channels by shield elements 56 built into the jig using materials known in the art, so that the effect of a particular electromagnetic coil is substantially limited to its respective channel. In this way, the magnetic attraction in each channel can be controlled independently.

The photovoltaic strips 53 that are aligned and held at the bottom of each channel may be oriented in one of two ways: either the active photovoltaic surface or the metallic film surface of each strip 53 may face upwards. The desired or active orientation is to have the photovoltaic surface of each strip 53 face upwards. Optical sensors 54 may be used to determine the side of the photovoltaic strip that is facing upwards at the bottom of each channel 52. As the active photovoltaic side of the strip will be dark and the side with metallic backing will be shiny, the intensity of light reflected back from the photovoltaic ribbon will indicate which side is facing upwards. Channels 52 with the photovoltaic ribbons in the active orientation will have their respective magnetic fields remain on; magnetic fields in the other channels will be turned off. Then all un-magnetized channels 52 will then be cleared of photovoltaic ribbons by air jet nozzles 55 or other suitable means.

The above process can be repeated until the optical sensors 54 indicate that all channels are filled with photovoltaic strips 53 in the proper (active) orientation. When this occurs, a concentrating shingle 100 with adhesive applied to the bottom of the concentrating lens elements 2 will be positioned into the magnetic jig 50 so that the adhesive surface makes contact with the photovoltaic strips 53. The magnetic fields holding the ribbons to the bottom of the channel 52 are then switched off, and the concentrating shingle 100 is removed from the jig with the photovoltaic ribbons properly attached.

The sequencing of the optical sensors and the switching of the electromagnets may be advantageously controlled by a programmable logic controller (not shown), in ways that are known in the art.

As would be clear to anyone skilled in the art, the descriptions of the invention and the accompanying drawings herein are intended to be illustrative only, and it will be apparent to one skilled in this art that various other design and structural changes may be made in the invention without departing from the spirit and scope thereof.

1. A planar solar energy concentrating unit comprising:
(a) a substantially light transparent first planar portion defined by upper and lower planes and having a plurality of light concentrating elements integrally formed in said first portion between said upper and lower planes with the concentrating geometries of said light concentrating elements oriented toward said upper plane; and,
(b) a substantially light transparent second planar portion adjoining the upper plane of said first planar portion.

2. A solar energy concentrating unit according to claim 1 wherein the integrally-formed light concentrating elements have a two-dimensional channel-like geometry.

3. A solar energy concentrating unit according to claim 1 wherein the integrally-formed light concentrating elements have a three-dimensional cone-like geometry.

4. A solar energy concentrating unit according to claim 1 adapted for roofing shingle applications by leaving at least a section along an edge of the unit without light concentrating elements formed therein.

5. A solar energy concentrating unit according to claim 1 further comprising a photovoltaic material located at a base region of a concentrating element so as to receive concentrated light from the concentrating element.

6. A solar energy concentrating unit according to claim 1 wherein said first and second planar portions are separately formed and thereafter adhered to one another.

7. A solar energy concentrating unit according to claim 1 wherein said first and second planar portions are integrally formed as a unitary structure.

8. A roofing structure comprising a plurality of solar energy concentrating units according to claim 1, each such unit being fastened along at least an edge to another such unit to form the roofing structure.

9. A roofing structure according to claim 8 further comprising spacing elements to space and support the solar energy concentrating units a distance above a roofing foundation.

10. A roofing structure according to claim 8 further wherein a photovoltaic material is located at a base region of a concentrating element so as to receive concentrated light from the concentrating element.

11. An electricity generating device comprising in combination a plurality of solar energy concentrating units according to claim 1, light absorbers formed of a photovoltaic material located at base regions of the concentrating units, and electric circuitry to collect electric energy produced by the light absorbers.

12. A method of fabricating a solar energy concentrating shingle comprising a light-receiving planar portion and a light-concentrating planar portion, said method comprising the step of integrally forming a plurality of light concentrating elements oriented toward said light-receiving portion in said light-concentrating portion.

13. A method according to claim 12 wherein the integrally-formed light concentrating elements have a two-dimensional channel-like configuration.

14. A method according to claim 12 wherein the integrally-formed light concentrating elements have a three-dimensional cone-like configuration.

15. A method according to claim 12 further comprising the step of locating a photovoltaic target at a base region of a concentrating element.

16. A method according to claim 15 further comprising the step of providing electric circuitry to collect electric energy produced by the photovoltaic targets.

17. A method according to claim 15 wherein a magnetic jig is used to apply and orient photovoltaic ribbons along the base regions of a plurality of channels comprising the light concentrating elements.

18. A method according to claim 17 wherein the photovoltaic ribbons consist essentially of copper indium di-selenide.

19. A method according to claim 12 further comprising the step of positioning optical elements between adjacent light concentrating elements to create color and/or texture visual effects in the shingle.

20. A solar energy device for converting sunlight to electricity made by integrally forming a plurality of light concentrating elements in a light-concentrating layer of a substantially light transparent two-layer planar structure such that the concentrating geometry of each light concentrating element is oriented toward a light-receiving layer of the planar structure.
